(19) United States
(12) Patent Application Publication
(10) Pub. No.: US 2012/0319718 A1
(43) Pub. Date: Dec. 20, 2012

(54) SIGNAL TRANSMISSION APPARATUS AND SEMICONDUCTOR TEST APPARATUS USING THE SAME

(75) Inventor: Sung Yeol Kim, Gyeonggi-do (KR)

(73) Assignee: SAMSUNG ELECTRONICS CO., LTD., Suwon-si (KR)

(21) Appl. No.: 13/430,902

(22) Filed: Mar. 27, 2012

(30) Foreign Application Priority Data
Jun. 14, 2011 (KR) 10-2011-0057166

(51) Int. Cl. G01R 31/26; H03F 1/00; H03H 7/00

(52) U.S. Cl. 324/762.01; 333/27; 330/1 R

(57) ABSTRACT

The semiconductor test apparatus includes a pin electronics unit. The pin electronics unit includes a driver configured to generate a test signal to be applied to a semiconductor device and a comparator configured to receive a response signal output from the semiconductor device and to convert the response signal into a digital signal. A first line is connected between the driver and a connector to which the external cable is connected. A second line diverges from the connector side of the first line. A probing unit is connected between the first and second lines, and is configured to at least reduce distortion of a signal on the first line to be transmitted to the second line. A divergence point at which the second line diverges from the first line is located outside the pin electronics unit near the connector.

### CROSS-REFERENCE TO RELATED APPLICATION

This application claims priority under 35 U.S.C. §119 to Korean Patent Application No. 2011-0057166, filed on Jun. 14, 2011 in the Korean Intellectual Property Office (KIPO), the entire contents of which are hereby incorporated herein by reference.

### BACKGROUND

1. Field

Embodiments relate to a signal transmission apparatus that performs two-way communication using a single external cable and a semiconductor test apparatus using the same.

2. Description of the Related Art

After manufacture of a semiconductor device, electrical properties of the semiconductor device are tested to confirm whether the semiconductor device operates normally. Such a test process is performed by a semiconductor test apparatus that tests a semiconductor device using a probe card or a test socket.

Such a semiconductor test apparatus has a signal transmission line to transmit a test signal to a semiconductor device under test. Based on its form, the signal transmission line may be classified as a single transmission line (STL) or a dual transmission line (DTL).

A semiconductor test apparatus having a single transmission line applies a test signal to a semiconductor device under test (hereinafter, DUT) through a driver and receives a DUT response signal through a comparator. The DUT response signal is compared with an expected value to determine whether the DUT operates normally.

Meanwhile, in the semiconductor test apparatus having the single transmission line, input/output dead time during which a test signal is not applied from the semiconductor test apparatus to the DUT is present based on an input/output transmission structure thereof.

In recent years, semiconductor devices operating at high speed have been developed, and therefore, a high-speed semiconductor test apparatus may be needed to test such semiconductor devices.

Reading and writing cycles are repeated at high speed to operate the DUT at high speed. If the input/output dead time is present, the semiconductor device may not be tested within the input/output dead time, with the result that high-speed test may not be achieved.

A method of extinguishing the input/output dead time using the dual transmission line has been proposed. In the dual transmission line, however, an external cable that is more expensive than in the single transmission line may be used.

### SUMMARY

At least one embodiment provides a semiconductor test apparatus connected to a semiconductor device under test via a single external cable. In one embodiment, a first line and a second line, connected to the first line via a probing unit, are provided between a driver and a comparator. A divergence point at which the second line diverges from the first line is located outside a pin electronics unit to reduce input/output dead time.

At least one embodiment provides a signal transmission apparatus that connects a first device and a second device using a single external cable to achieve two-way communication. In one embodiment, a first line and a second line, diverging from the first line and connected to the first line via a probing unit, are provided between a transmitting unit and a receiving unit. A divergence point at which the second line diverges from the first line is located outside a communication interface to reduce input/output dead time.

Additional aspects of the embodiments will be set forth in part in the description which follows and, in part, will be obvious from the description, or may be learned by practice of the invention.

In one embodiment, a semiconductor test apparatus connected to a semiconductor device under test via an external cable to test electrical properties of the semiconductor device includes a pin electronics unit. The pin electronics unit includes a driver configured to generate a test signal to be applied to the semiconductor device and a comparator configured to receive a response signal output from the semiconductor device and to convert the response signal into a digital signal. A first line is connected between the driver and a connector to which the external cable is connected. A second line diverges from the first line at an end closer to the connector. A probing unit is connected between the first line and the second line, and is configured to at least reduce distortion of a signal on the first line to be transmitted to the second line. A divergence point at which the second line diverges from the first line is located outside the pin electronics unit near the connector.

The probing unit may include a resistance element or an amplifier.

The external cable may include a coaxial cable and the first line and the second line may form a transmission line on a printed circuit board (PCB).

The semiconductor test apparatus may further include an amplifier unit connected to the second line at an end closer to the comparator. The amplifier is configured to amplify a signal having passed through the probing unit.

The amplifier unit may be connected between the comparator and the probing unit.

In another embodiment, a signal transmission apparatus that connects a first device and a second device to each other using an external cable to achieve two-way communication includes a communication interface including a transmitting unit and a receiving unit. A first line is connected between the transmitting unit and a connector to which the external cable is connected. A second line diverges from the first line at an end closer to the connector. A probing unit is located between the first line and the second line. The probing unit is configured to at least reduce distortion of a signal on the first line to be transmitted to the second line. A divergence point at which the second line diverges from the first line is located outside the communication interface near the connector.

The external cable may include a coaxial cable and the first line and the second line may form a transmission line on a PCB.

The probing unit may include a resistance element or an amplifier.

The signal transmission apparatus may further include an amplifier unit connected to the second line an end closer to the receiving unit. The amplifier is configured to amplify a signal having passed through the probing unit.

The amplifier unit may be connected between the receiving unit and the probing unit.

### BRIEF DESCRIPTION OF THE DRAWINGS

Example embodiments will be more clearly understood from the following brief description taken in conjunction with the accompanying drawings. FIGS. 1-10 represent non-limiting, example embodiments as described herein.

FIG. 1 is a block diagram schematically showing the construction of a semiconductor test apparatus according to an embodiment;

FIG. 2 is a view showing a general signal transmission structure of the semiconductor test apparatus shown in FIG. 1;

FIG. 3 is a view showing an example of signal waveforms input and output in the signal transmission structure of FIG. 2;

FIG. 4 is a view showing an example of signal waveforms input and output in the signal transmission structure of FIG. 2;

FIG. 5 is a view showing a signal transmission structure according to an embodiment of the semiconductor test apparatus;

FIG. 6 is a view showing an example of signal waveforms input and output in the signal transmission structure of FIG. 5;

FIG. 7 is a view showing a signal transmission structure according to another embodiment of the semiconductor test apparatus;

FIG. 8 is a view showing an example of signal waveforms input and output in the signal transmission structure of FIG. 7;

FIG. 9 is a block diagram showing the construction of a signal transmission apparatus according to another embodiment; and

FIG. 10 is a block diagram showing the construction of a signal transmission apparatus according to a further embodiment.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments will now be described more fully with reference to the accompanying drawings, in which example embodiments are shown. Example embodiments may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

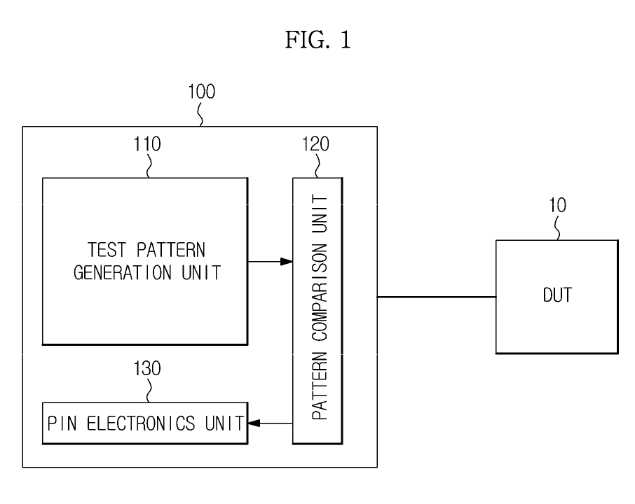

FIG. 1 is a block diagram schematically showing the construction of a semiconductor test apparatus according to an embodiment.

Referring to FIG. 1, a semiconductor test apparatus 100 may be connected to a device under test (DUT) 10, such as a semiconductor, via an external cable.

Meanwhile, the DUT 10 may be connected to the external cable via a device interface. The device interface may include a board to apply a signal and power from the semiconductor test apparatus 100 to an input pin and power pin of the DUT 10 and may transmit a signal from an output pin of the DUT 10 to the semiconductor test apparatus 100 and a connector connected to the external cable.

The semiconductor test apparatus 100 may include a test board having a test pattern generation unit 110, a pin electronics unit 120 and a pattern comparison unit 130.

The test pattern generation unit 110 may create a timing signal, which may be a reference signal to drive an external device (DUT, etc.) and may generate a drive signal that may be synchronized with the timing signal. Here, the drive signal may include a command signal, address signal and data signal.

Also, the test pattern generation unit 110 may calculate an expected value corresponding to the generated drive signal and may transmit the expected value to the pattern comparison unit 130.

That is, the test pattern generation unit 110 may generate (1) a clock signal, which may be a reference signal to drive the DUT, and (2) a drive signal, which may be information as to what data may be written to or read from what address of the DUT 10.

The pin electronics unit 120 may convert the drive signal transmitted from the test pattern generation unit 110 into a voltage level (that is, a physical signal) recognizable by the semiconductor and may transmit the converted voltage level to the DUT 10 via a driver. Here, the voltage level may be a test signal to test the DUT 10.

Also, the pin electronics unit 120 may compare the DUT response signal transmitted from the DUT 10 with a critical voltage value through a comparator and may convert the DUT response signal into a digital signal. The comparator may transmit logical data of the DUT response signal converted into the digital signal to the pattern comparison unit 130.

The pattern comparison unit 130 may determine whether the DUT is defective using the expected value transmitted from the test pattern generation unit 110 and the logical value of the DUT response signal transmitted from the comparator of the pin electronics unit 120.

Specifically, the pattern comparison unit 130 may determine whether the logical value of the DUT response signal coincides with the expected value corresponding thereto. If the logical value of the DUT response signal coincides with the expected value, the pattern comparison unit 130 may determine that the DUT is defective. Upon determining that the DUT is defective, information on the logical value and the expected value may be stored in a memory.

In this example embodiment, the semiconductor test apparatus may be constituted by a single test board with the above-stated construction. Alternatively, a plurality of test boards may be connected to each other to constitute the semiconductor test apparatus.

In this case, the test pattern generation unit, the pin electronics unit and the pattern comparison unit may be provided in each of the test boards. The test boards may be connected to a plurality of DUTs, respectively.

Hereinafter, a signal transmission structure of the semiconductor test apparatus shown in FIG. 1, which performs two-way communication with the DUT and waveforms in the signal transmission structure, will be described.

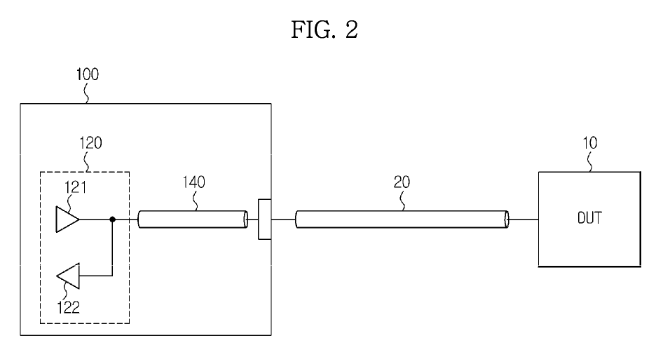

FIG. 2 is a view showing a general signal transmission structure of the semiconductor test apparatus.

Referring to FIG. 2, the signal transmission structure of the semiconductor test apparatus 100 may include the pin electronics unit 120, a printed circuit board (PCB) transmission line 140 connected between the pin electronics unit 120 and a connector, an external cable 20 connected to the PCB transmission line via the connector and input and output pins of the DUT 10.

The pin electronics unit 120 may include a driver 121 to generate a test signal and a comparator 122 to convert a DUT response signal into a digital signal.

An output terminal of the driver 121 may be connected to an input terminal of the comparator 122. A lumped circuit model may be connected between the driver 121 and the comparator 122. Consequently, a driver drive signal is received by the comparator 122 without transmission delay time at a principal frequency band. That is, the connection between the driver 121 and the comparator 122 in the pin electronics unit 120 is not considered to be a general transmission line having transmission delay.

In this example embodiment, the transmission line of the semiconductor test apparatus may include the PCB transmission line and the external cable. The transmission line may have delay time. As a result, a signal transmitted between the semiconductor test apparatus and the DUT after the delay time.

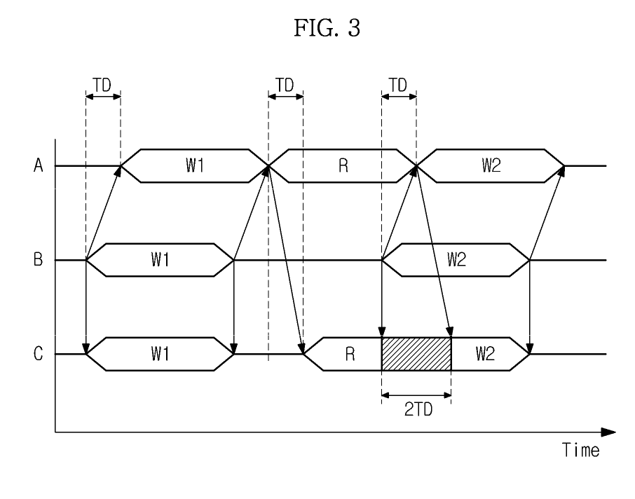

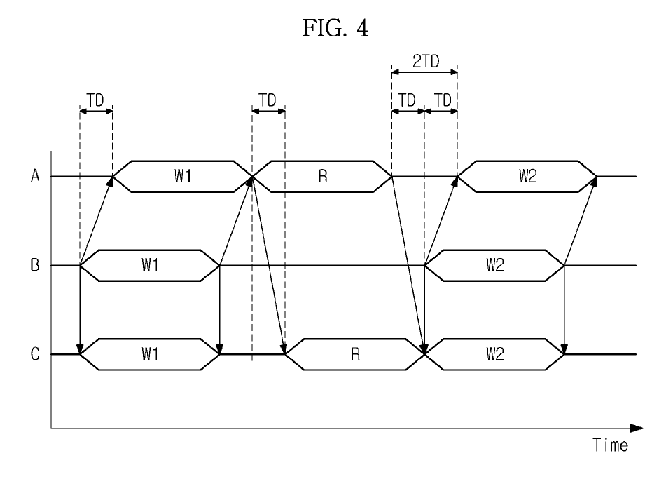

In the signal transmission structure with the above-stated construction, signal waveforms of the test signal and the DUT response signal are shown in FIGS. 3 and 4. Meanwhile, in FIGS. 3 and 4, A indicates a signal waveform of the DUT based on time, B indicates a signal waveform of the driver and C indicates a signal waveform of the comparator. Also, it may be assumed that a test signal generated by the driver is transmitted to the DUT after transmission delay time TD and, in the same manner, the DUT response signal is transmitted to the comparator after the transmission delay time TD.

Meanwhile, the transmission delay time may be delay time of the transmission line in the semiconductor test apparatus. The transmission line may include the PCB transmission line and the external cable. That is, the transmission delay time may be the sum of the delay time of the PCB transmission line and the delay time of the external cable.

Referring to FIG. 3, when a test signal W1 is output from the driver B, the test signal W1 may be transmitted to the DUT A via the transmission line after the transmission delay time TD. On the other hand, the test signal W1 may be directly transmitted to the comparator C without transmission delay.

When the transmission of the test signal W1 to the DUT A is completed, the DUT A outputs a DUT response signal R. In the same manner, the DUT response signal R may pass through the transmission line and may be transmitted to the comparator C after the transmission delay time TD.

Meanwhile, in FIG. 3, the driver B outputs the next test signal W2 while the comparator C receives the DUT response signal R. The output test signal W2 may be transmitted to the DUT A after the transmission delay time TD and, at the same time, may be directly transmitted to the comparator C. As a result, the DUT response signal R and the test signal W2 may collide with each other at the comparator C side, and therefore, normal tests may not be possible.

Consequently, as shown in FIG. 4, transmission of a test signal to the DUT A is restricted for a time period. The time period may be an input/output dead time (I/O dead time), which may be set to twice or more the transmission delay time.

That is, the semiconductor test apparatus may not apply a test signal to the DUT during the I/O dead time (2TD) after output of the DUT response signal is completed.

If the I/O dead time is long, a semiconductor device operating at high speed may not be tested.

Hereinafter, the signal transmission structure of the semiconductor test apparatus to reduce the I/O dead time will be described.

First, the I/O dead time may be needed since, as described above, data are transmitted between the semiconductor test apparatus and the DUT after the delay time whereas data are transmitted between the driver and the comparator in the pin electronics unit of the semiconductor test apparatus without delay. As a result, in the comparator, the test signal from the driver and the DUT response signal may collide with each other.

Consequently, it may be desirable to configure the semiconductor test apparatus so that a delay time is present between the driver and the comparator so as to reduce the I/O dead time. That is, it may be desirable to configure the semiconductor test apparatus so that the test signal from the driver is transmitted to the comparator after the delay time.

If the test signal from the driver is transmitted to the comparator via the DUT through the structure of a dual transmission line DTL having two external cables, the test signal may be successively transmitted to the comparator without the I/O dead time.

However, the signal transmission structure based on the dual transmission line may be expensive. In this example embodiment, therefore, the signal transmission structure may use a single external cable and the PCB transmission line having a delay time may be connected between the driver and the comparator so that the delay time is present between the driver and the comparator.

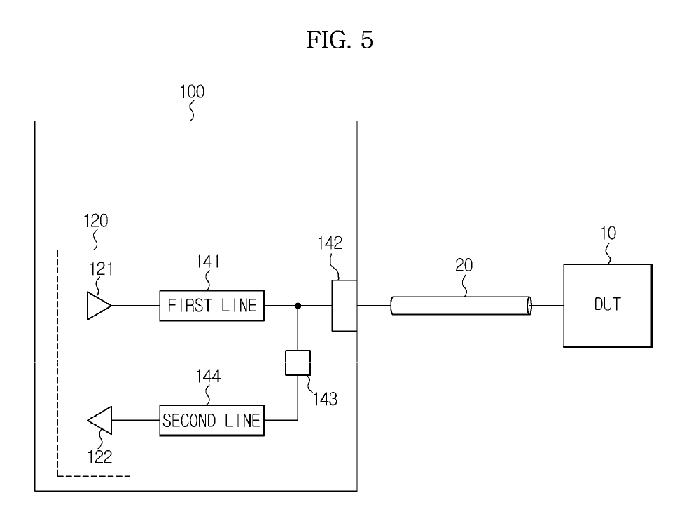

Hereinafter, a signal transmission structure according to an example embodiment of the semiconductor test apparatus will be described with reference to FIG. 5.

Referring to FIG. 5, the signal transmission structure of the semiconductor test apparatus 100 may include a pin electronics unit 120, which may include a driver 121 and a comparator 122; a first line 141 connected between the driver 121 and an external cable 20; a second line 144, which may diverge from one side of the first line 141 and connected to the comparator 121; and a probing unit 143 connected between the first line 141 and the second line 144.

Particularly in the signal transmission structure of the semiconductor test apparatus 100 according to this example embodiment, a PCB transmission line including the first line and the second line may be connected between the driver 121 and the comparator 122. Also, a divergence point at which the second line 144 diverges from the first line 141 may be located outside the pin electronics unit 120. The divergence point may be located outside the pin electronics unit 120 so that the divergence point is maximally near a connector 142.

In this example embodiment, the first line 141 and the second line 144 may constitute a transmission line on a PCB. The divergence point at which the second line 144 diverges from the first line 141 may be located outside a chip of the pin electronics unit 120 and the external cable may be a coaxial cable.

Meanwhile, in this example embodiment, the first line 141 and the second line 144 may have the same length. Alternatively, the first line 141 and the second line 144 may have different lengths.

Also, in this example embodiment, the probing unit 143 may be connected between the first line 141 and the second line 144 to reduce or prevent distortion of a signal on the first line 141 due to the increase in length of the second line 144.

The probing unit 143 may be a resistance element or an amplifier. If the probing unit 143 is a resistance element, the resistance element may have resistance equivalent to ten times or more characteristic impedance of the first line 141.

Consequently, a signal on the first line 141 having reduced or minimized distortion, and damped amplitude, may be received by the comparator connected to one end of the second line 144.

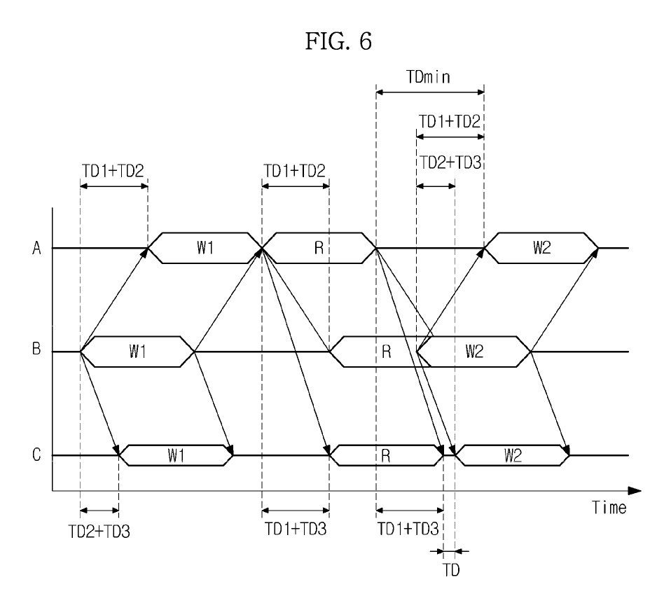

The semiconductor test apparatus with the above-stated construction has signal transmission waveforms as shown in FIG. 6.

In FIG. 6, A indicates a signal waveform of the DUT based on time, B indicates a signal waveform of the driver and C indicates a signal waveform of the comparator. Also, it may be assumed that transmission delay time of the external cable is TD1, transmission delay time of the first line is TD2 and transmission delay time of the second line is TD3.

Meanwhile, in this example embodiment, the first line and the second line may have the same delay time. Alternatively, delay time of the first line may be different from delay time of the second line based on lengths of the first and second lines.

Referring to FIG. 6, test signals W1 and W2 may be transmitted from the driver B of the pin electronics unit 120 to an input pin of the DUT A via the first line and the external cable. Also, a DUT response signal R may be generated as the result of application of the test signals W1 and W2 is transmitted from an output pin of the DUT to the comparator C of the pin electronics unit 120 via the external cable and the second line.

Specifically, when the test signal W1 is output from the driver B, the test signal W1 is applied to the DUT A via the first line and the external cable after transmission delay time TD1+TD2. Also, the test signal W1 may be transmitted to the comparator C via the first line and the second line after transmission delay time TD2+TD3.

When transmission of the test signal W1 to the DUT A is completed, the DUT A may output a DUT response signal R. The DUT response signal R may be transmitted to the driver B and the comparator C via the first line or the second line.

Specifically, the DUT response signal R may be transmitted to the driver B via the external cable and the first line after transmission delay time TD1+TD2 and to the comparator C via the external cable and the second line after transmission delay time TD1+TD3.

The driver B outputs the second test signal W2 to the DUT. In the same manner, the test signal W1 is transmitted to the DUT A after transmission delay time TD1+TD2 and to comparator C after transmission delay time TD2+TD3.

Meanwhile, in the signal waveform of the driver B, the DUT response signal R and the test signal W2 may overlap each other. This, however, does not affect the overall test operation due to properties of a traveling wave since the DUT response signal R is extinguished by terminating resistance in the driver B.

The second test signal W2 may be adjusted to be received by the DUT A after I/O dead time TDmin.

TDmin is time to prevent collision between the DUT response signal R and the test signal W2 at the signal waveform of the comparator C and thus time satisfying a condition in which distance TD between the DUT response signal R and the test signal W2 may be 0 or more.

TD may be obtained based on mathematical expressions 1 and 2.

T2=TDmin−(TD1+TD2)+(TD2+TD3)

T1=TD1+TD3 <Mathematical expression 1>

$$\begin{matrix}TD = T 2 - T 1 \\ = TD min - {2}^{*} T D 1\end{matrix} \qquad < Mathematial expression 2 >$$

Where, TD is TDmin−2*TD1, and therefore, TDmin is 2*TD1 or more. That is, in this example embodiment, the I/O dead time TDmin may be decided based on TD1, which is the delay time of the external cable irrespective of TD2 and TD3, which are the delay times of the PCB transmission line.

Meanwhile, average transmission speed of the PCB transmission line may be about 0.45 times the speed of light and average transmission speed of the external cable, which may be a coaxial cable, is 0.7 times the speed of light. For this reason, transmission speed may be greatly affected by the PCB transmission line.

In this example embodiment, therefore, the I/O dead time may be effectively reduced. For example, if an external cable having a transmission delay time of 1.38 ns is used, the I/O dead time may be 2.76 ns. In this example embodiment, the I/O dead time satisfies Table 1 indicating a condition of I/O dead time in testing mobile DRAM elements.

TABLE 1

| mDRAM transmission speed (Mbps) | 1066 | 800 | 667 |
|---|---|---|---|
| Minimum I/O dead time condition TDmin (ns) | 3.4 | 6.4 | 5.8 |

In Table 1, the I/O dead time (2.76 ns) of this example embodiment may be less than the I/O dead time (3.4 ns, 6.4 ns, 5.8 ns) to test mobile DRAMs and may thus be suitable for testing of high-speed mobile DRAMs.

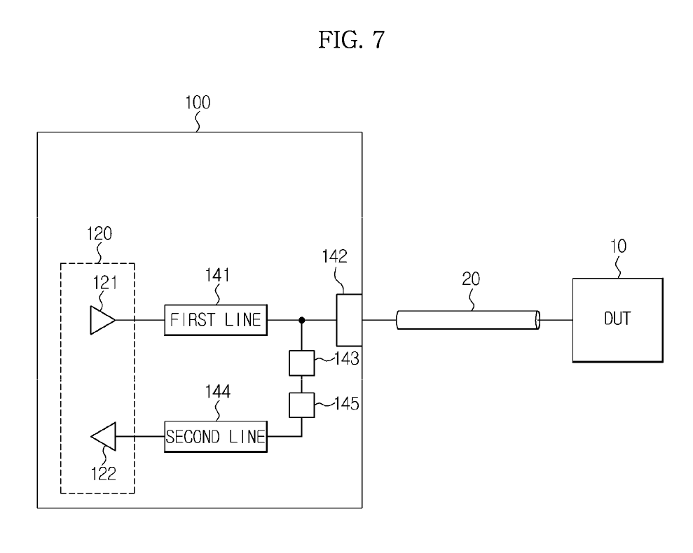

FIG. 7 is a view showing a signal transmission structure according to another embodiment of the semiconductor test apparatus.

Referring to FIG. 7, the signal transmission structure of the semiconductor test apparatus 100 may include a pin electronics unit 120, which may include a driver 121 and a comparator 122; a first line 141 connected between the driver 121 and an external cable 20; a second line 144, which may diverge from one side of the first line 141 and may be connected to the comparator 121; and a probing unit 143 connected between the first line 141 and the second line 144.

In particular, the signal transmission structure of the semiconductor test apparatus 100 according to this example embodiment may further include an amplifier unit 145 connected to the second line 144. The amplifier unit 145 may be connected between the probing unit 143 and the comparator 122 to amplify a signal having passed through the probing unit 143. Specifically, the amplifier unit 145 may be connected to the second line 144 at the comparator 122 side so that the amplifier unit 145 is near the probing unit 143.

This connection may be provided to increase amplitude of a signal on the second line 144, the amplitude of which may be damped as compared with a signal on the first line 141 as the result of passing through the probing unit 143. Consequently, the same signal as that of the first line 141 may be applied to the comparator 122.

Meanwhile, the other parts of the signal transmission structure shown in FIG. 7 are identical to those of FIG. 5, and therefore, a description thereof will be omitted.

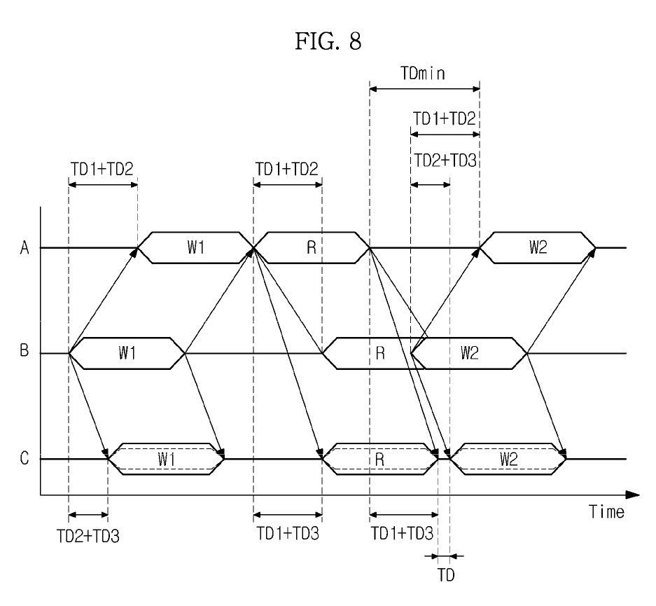

The signal transmission structure of FIG. 7 may have signal transmission waveforms as shown in FIG. 8.

Referring to FIG. 8, a signal of the comparator C is amplified by the amplifier unit 145 unlike a signal of the comparator (dotted line) amplitude of which may be damped as the result of passing through the probing unit 143.

The other signal transmission waveforms shown in FIG. 8 and conditions of I/O dead time may be identical to those of FIG. 6, and therefore, a description thereof will be omitted.

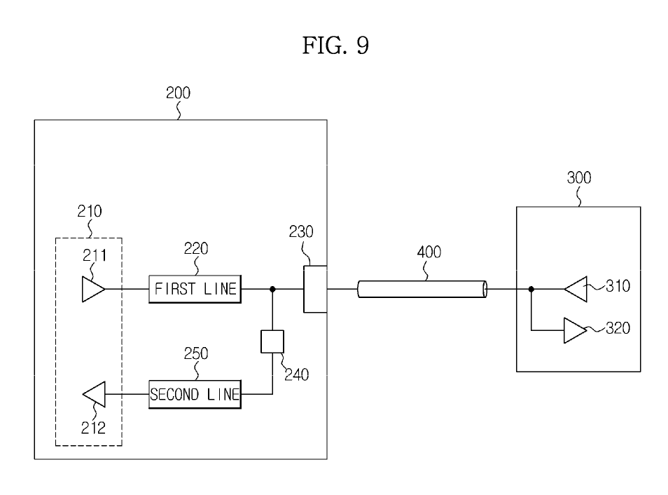

FIG. 9 is a block diagram showing the construction of a signal transmission apparatus according to another embodiment.

Referring to FIG. 9, the signal transmission apparatus according to this example embodiment may be configured so that a first device 200 and a second device 300 may be connected to each other via a signal external cable 400 to achieve two-way communication.

In this example embodiment, the signal transmission apparatus may include a communication interface 210. The communication interface 210 may include a transmitting unit 211 to transmit a signal and a receiving unit 212 to receive a signal. A first line 220 may be connected between the transmitting unit 211 and a connector 230, to which an external cable 400 may be connected. A second line 250, may diverge from one side of the first line 220, and be connected to the receiving unit 212. A probing unit 240 may be connected between the first line 220 and the second line 250.

Particularly in the signal transmission apparatus according to this example embodiment, the transmitting unit 211 and the receiving unit 212 may be connected to the first line 220 and the second line 250, respectively. The first and second lines 220 and 250 may constitute a PCB transmission line. Also, a divergence point at which the second line 250 diverges from the first line 220 may be located outside the communication interface 210. The divergence point may be located outside the communication interface 210 so that the divergence point may be maximally near the connector 230.

Also, in this example embodiment, the probing unit 240 may be connected between the first line 220 and the second line 250 to reduce or prevent distortion of a signal on the first line 220 due to the increase in length of the second line 250.

The probing unit 240 may be a resistance element or an amplifier. If the probing unit 240 is a resistance element, the resistance element may have resistance equivalent to ten times or more characteristic impedance of the first line 220.

Consequently, a signal on the first line 220 may have reduced or minimized distortion, and damped amplitude; and may be received by the receiving unit 212 connected to one end of the second line 250.

Meanwhile, in this example embodiment, the first line 220 and the second line 250 may have the same length. Alternatively, the first line 220 and the second line 250 may have different lengths.

Also, in this example embodiment, the divergence point at which the second line diverges from the first line may be located outside the communication interface. The components of the signal transmission apparatus such as the probing unit may be provided in the first device. Alternatively, the components of the signal transmission apparatus may be provided in the second device 300. That is, the components of the signal transmission apparatus may be provided in the first device 200 or the second device 300.

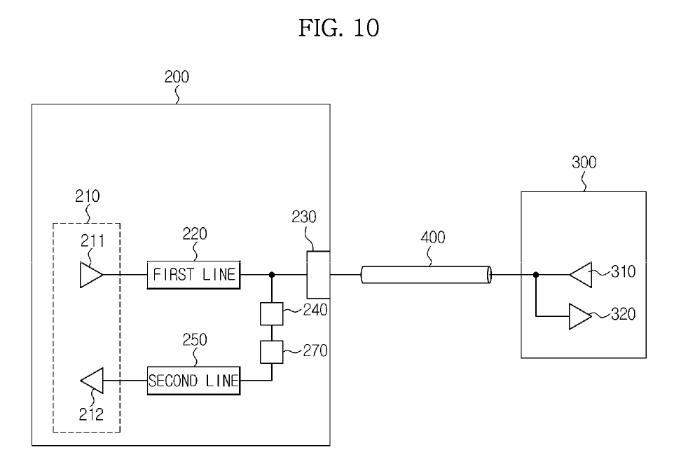

FIG. 10 is a block diagram showing the construction of a signal transmission apparatus according to a further embodiment.

Referring to FIG. 10, the signal transmission apparatus according to this example embodiment may further include an amplifier unit 260 connected between a receiving unit 212 and a probing unit 240 to amplify a signal, the amplitude of which may be damped as the result of passing through the probing unit 240. Specifically, the amplifier unit 260 may be connected to a second line 250 at the receiving unit 212 side so that the amplifier unit 260 is near the probing unit 240.

The other parts of the signal transmission apparatus shown in FIG. 10 are identical to those of FIG. 9, and therefore, a description thereof will be omitted.

In the signal transmission apparatus according to each of the above example embodiments and the semiconductor test apparatus using the same, a single external cable may be used and the divergence point at which the second line diverges from the first line between the driver and the comparator may be located outside the pin electronics unit to reduce the I/O dead time. Consequently, a semiconductor device operating at high speed may be tested, and therefore, a test range may be extended.

Also, the probing unit may be connected between the first line and the second line. Consequently, a signal on the first line may be transmitted to the second line in a state in which distortion of the signal may be reduced or minimized.

Also, a single external cable may be used. Consequently, cost may be reduced as compared with the dual transmission line, and therefore, a plurality of semiconductor devices may be tested.

While example embodiments have been particularly shown and described, it will be understood by one of ordinary skill in the art that variations in form and detail may be made therein without departing from the spirit and scope of the claims.

1. A semiconductor test apparatus connected to a semiconductor device under test via an external cable to test electrical properties of the semiconductor device, comprising:
a pin electronics unit including a driver and comparator, the driver configured to generate a test signal to be applied to the semiconductor device, and the comparator configured to receive a response signal output from the semiconductor device and to convert the response signal into a digital signal;
a first line connected between the driver and a connector to which the external cable is connected;
a second line diverging from the first line at an end closer to the connector; and
a probing unit connected between the first line and the second line, the probing unit configured to at least reduce distortion of a signal on the first line to be transmitted to the second line, wherein
a divergence point at which the second line diverges from the first line is located outside the pin electronics unit near the connector.

2. The semiconductor test apparatus according to claim 1, wherein the probing unit comprises a resistance element or an amplifier.

3. The semiconductor test apparatus according to claim 1, wherein
the external cable comprises a coaxial cable, and
the first line and the second line form a transmission line on a printed circuit board (PCB).

4. The semiconductor test apparatus according to claim 1, further comprising:
an amplifier unit connected to the second line at an end closer to the comparator, the amplifier configured to amplify a signal having passed through the probing unit.

5. The semiconductor test apparatus according to claim 4, wherein the amplifier unit is connected between the comparator and the probing unit.

6. A signal transmission apparatus that connects a first device and a second device to each other using an external cable to achieve two-way communication, comprising:
a communication interface including a transmitting unit and a receiving unit;
a first line connected between the transmitting unit and a connector to which the external cable is connected;
a second line diverging from the first line an end closer to the connector; and
a probing unit located between the first line and the second line, the probing unit configured to at least reduce distortion of a signal on the first line to be transmitted to the second line, wherein
a divergence point at which the second line diverges from the first line is located outside the communication interface near the connector.

7. The signal transmission apparatus according to claim 6, wherein
the external cable comprises a coaxial cable, and
the first line and the second line form a transmission line on a PCB.

8. The signal transmission apparatus according to claim 6, wherein the probing unit comprises a resistance element or an amplifier.

9. The signal transmission apparatus according to claim 6, further comprising:
an amplifier unit connected to the second line at an end closer to the receiving unit, the amplifier configured to amplify a signal having passed through the probing unit.

10. The signal transmission apparatus according to claim 9, wherein the amplifier unit is connected between the receiving unit and the probing unit.
